(19) United States
(12) Patent Application Publication
(10) Pub. No.: US 2026/0179715 A1
(43) Pub. Date: Jun. 25, 2026

(54) STORAGE CONTROLLER PERFORMING ODT TRAINING, METHOD OF OPERATING THE SAME, AND METHOD OF OPERATING STORAGE SYSTEM INCLUDING THE SAME

(71) Applicant: Samsung Electronics Co., Ltd., Suwon-si (KR)

(72) Inventors: Seung Hyeon Yun, Suwon-si (KR); Jindo Byun, Suwon-si (KR); Kyoungtae Kang, Suwon-si (KR); Eun Seok Shin, Suwon-si (KR); Youngdon Choi, Suwon-si (KR)

(21) Appl. No.: 19/331,284

(22) Filed: Sep. 17, 2025

(30) Foreign Application Priority Data
Dec. 23, 2024 (KR) 10-2024-0194281

(51) Int. Cl. G11C 29/56

(52) U.S. Cl. CPC G11C 29/56012; G11C 29/56016

(57) ABSTRACT

Disclosed is an operating method of a storage controller which communicates with a non-volatile memory device. The method may include detecting first to N-th sampling signals at respective time points at which first to N-th delay times sequentially elapse, determining the N-th sampling signal having a first voltage level higher than a first reference voltage level as a first target sampling signal, determining a K-th sampling signal last having a third voltage level lower than a second reference voltage level as a second target sampling signal, and controlling an on-die termination (ODT) resistance of the non-volatile memory device such that a first difference between a fourth voltage level of a third target sampling signal detected at a time point at which the N-th delay time elapses and the third voltage level is smaller than a threshold value.

### CROSS-REFERENCE TO RELATED APPLICATIONS

This application claims priority under 35 U.S.C. § 119 to Korean Patent Application No. 10-2024-0194281 filed on Dec. 23, 2024, in the Korean Intellectual Property Office, the disclosure of which is incorporated by reference herein in its entirety.

### BACKGROUND

Embodiments of the present disclosure described herein relate to a storage controller performing on-die termination (ODT) training, and more particularly, relate to a storage controller performing ODT training, an operating method of the storage controller, and an operating method of a storage system including the storage controller.

A memory device may store data in response to a write request and may output data stored therein in response to a read request. For example, the memory device may be classified as a volatile memory device, which loses data stored therein when a power is turned off, such as a dynamic random access memory (DRAM) device or a static RAM (SRAM) device, or a non-volatile memory device, which retains data stored therein even when a power is turned off, such as a flash memory device, a phase-change RAM (PRAM), a magnetic RAM (MRAM), or a resistive RAM (RRAM).

In general, interface circuits connecting a storage controller and a non-volatile memory device may experience the reflection of a data signal due to impedance discontinuity. The reflection of the data signal may cause the distortion of the data signal, thereby reducing the performance of the memory device. Accordingly, a method capable of reducing the reflection of the data signal may be beneficial.

### SUMMARY

Embodiments of the present disclosure provide a storage controller performing ODT training, an operating method of the storage controller, and an operating method of a storage system including the storage controller.

According to some embodiments, an operating method of a storage controller which communicates with a non-volatile memory device may include detecting first to N-th sampling signals at respective time points at which first to N-th delay times sequentially elapse, after providing a first test signal to the non-volatile memory device, determining the N-th sampling signal having a first voltage level higher than a first reference voltage level as a first target sampling signal, the first reference voltage level being higher than a second voltage level of the first test signal and being lower than two times the second voltage level, determining a K-th sampling signal, from among the first to N-th sampling signals, last having a third voltage level lower than a second reference voltage level as a second target sampling signal, the second reference voltage level being lower than the first reference voltage level, and controlling an on-die termination (ODT) resistance of the non-volatile memory device such that a first difference between a fourth voltage level of a third target sampling signal detected at a time point at which the N-th delay time elapses and the third voltage level is smaller than a threshold value, after providing a second test signal to the non-volatile memory device, and “K” is an integer greater than 1, and “N” is an integer greater than “K”.

According to some embodiments, a storage controller may include an interface circuit configured to provide a first test signal and a second test signal to a non-volatile memory device, and to detect first to N-th sampling signals at respective time points at which first to N-th delay times sequentially elapse, after providing the first test signal to the non-volatile memory device, a training module configured to generate an on-die termination (ODT) control signal for controlling an ODT resistance of the non-volatile memory device, a voltage generator configured to generate a voltage having a first reference voltage level and a second reference voltage level, and a timing circuit configured to provide a time signal indicating the first to N-th delay times to the interface circuit. The interface circuit may be configured to determine the N-th sampling signal having a first voltage level higher than the first reference voltage level as a first target sampling signal, and to determine a K-th sampling signal, from among the first to N-th sampling signals, last having a third voltage level lower than the second reference voltage level as a second target sampling signal. After the second test signal is provided to the non-volatile memory device, the training module may be configured to determine a final resistance value of the ODT resistance such that a first difference between a fourth voltage level of a third target sampling signal detected at a time point at which the N-th delay time elapses and the third voltage level is smaller than a threshold value. The first reference voltage level may be higher than a second voltage level of the first test signal and may be lower than two times the second voltage level. The second reference voltage level may be lower than the first reference voltage level. “K” is an integer greater than 1, and “N” is an integer greater than “K”.

According to some embodiments, an operating method of a storage system which includes a non-volatile memory device and a storage controller may include detecting, by the storage controller, first to N-th sampling signals at respective time points at which first to N-th delay times sequentially elapse, after providing a first test signal to the non-volatile memory device, determining, by the storage controller, the N-th sampling signal having a first voltage level higher than a first reference voltage level as a first target sampling signal, the first reference voltage level being higher than a second voltage level of the first test signal and being lower than two times the second voltage level, determining, by the storage controller, a K-th sampling signal, from among the first to N-th sampling signals, last having a third voltage level lower than a second reference voltage level as a second target sampling signal, the second reference voltage level being lower than the first reference voltage level, and controlling, by the storage controller, an on-die termination (ODT) resistance of the non-volatile memory device such that a first difference between a fourth voltage level of a third target sampling signal detected at a time point at which the N-th delay time elapses and the third voltage level is smaller than a threshold value, after providing a second test signal to the non-volatile memory device. “K” is an integer greater than 1, and “N” is an integer greater than “K”.

### BRIEF DESCRIPTION OF THE FIGURES

The above and other objects and features of the present disclosure will become more apparent by describing in detail example embodiments thereof with reference to the accompanying drawings.

FIG. 1 is a block diagram of a storage system according to some embodiments of the present disclosure.

FIG. 2 is a block diagram illustrating a storage system of FIG. 1 in more detail, according to some embodiments of the present disclosure.

FIG. 3 is a flowchart illustrating an operating method of a storage controller according to some embodiments of the present disclosure.

FIG. 4 is a graph illustrating a change in a voltage level according to some embodiments of the present disclosure.

FIG. 5 is a block diagram illustrating a storage controller according to some embodiments of the present disclosure.

FIG. 6 is a diagram illustrating a non-volatile memory device according to some embodiments of the present disclosure.

FIG. 7 is a diagram illustrating a non-volatile memory device according to some embodiments of the present disclosure.

FIG. 8 is a diagram illustrating a storage controller according to some embodiments of the present disclosure.

FIG. 9 is a flowchart illustrating an operating method of a storage controller according to some embodiments of the present disclosure.

FIG. 10 is a flowchart illustrating an operating method of a storage controller according to some embodiments of the present disclosure.

FIG. 11 is a flowchart illustrating an operating method of a storage controller according to some embodiments of the present disclosure.

FIG. 12 is a flowchart illustrating an operating method of a storage controller according to some embodiments of the present disclosure.

### DETAILED DESCRIPTION

Hereinafter, example embodiments of the present disclosure will be described in detail and clearly to such an extent that one skilled in the art may easily carry out embodiments of the present disclosure.

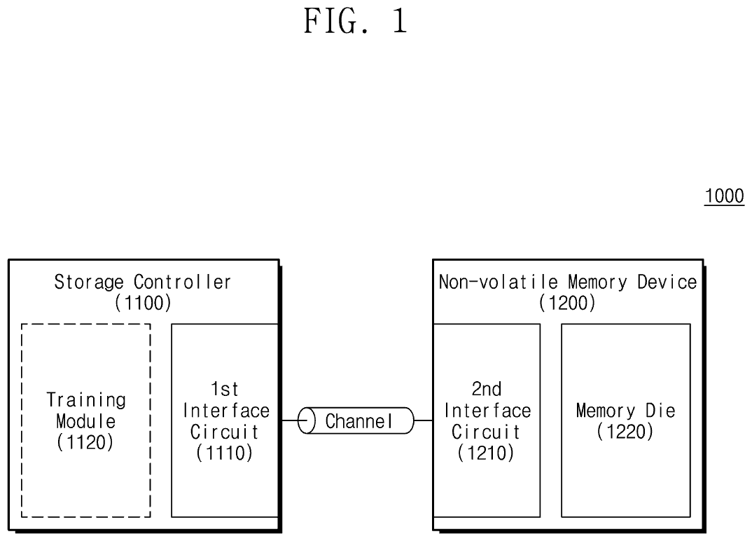

FIG. 1 is a block diagram of a storage system according to some embodiments of the present disclosure. Referring to FIG. 1, a storage system 1000 may include a storage controller 1100 and a non-volatile memory device 1200.

The storage controller 1100 may store data in the non-volatile memory device 1200 or may read data stored in the non-volatile memory device 1200. For example, based on a command indicating an operation to be performed and an address indicating a location of data, the storage controller 1100 may store data in the non-volatile memory device 1200 or may read data stored in the non-volatile memory device 1200.

The storage controller 1100 may control all operations of the non-volatile memory device 1200. For example, the storage controller 1100 may control a second interface circuit 1210 to perform impedance matching of the non-volatile memory device 1200. The storage controller 1100 may train an on-die termination (ODT) resistance of the second interface circuit 1210 to perform impedance matching.

The storage controller 1100 may include a first interface circuit 1110 and a training module 1120. The first interface circuit 1110 may transmit data to be stored in the non-volatile memory device 1200 to the non-volatile memory device 1200 or may receive data read from the non-volatile memory device 1200. The first interface circuit 1110 may be implemented to comply with the standard protocol such as Toggle or ONFI.

The first interface circuit 1110 may be connected to the second interface circuit 1210 of the non-volatile memory device 1200 through a channel. The first interface circuit 1110, the channel, and the second interface circuit 1210 may have different impedance values or different resistance values. In this case, data or signals transmitted/received through the first interface circuit 1110, the channel, and the second interface circuit 1210 may be reflected.

The reflection of the data or signals may cause the distortion of data or a signal in the storage system 1000. Accordingly, to minimize the occurrence of the reflection of the data or signals, there is an increasing need to perform impedance matching in the first interface circuit 1110, the channel, and the second interface circuit 1210. In particular, the impedance matching may be performed by training the ODT resistance in the second interface circuit 1210.

A conventional storage system may train the ODT resistance by using the Shmoo technique to perform impedance matching. However, to use the Shmoo technique, there may be a need to measure a lot of data for respective resistance values of the ODT resistance. Also, when the eye diagram is not opened, it is impossible to use the Shmoo technique to train the ODT resistance. Accordingly, the conventional storage system using the Shmoo technique may require a lot of time and a lot of costs to train the ODT resistance for impedance matching.

Unlike the conventional storage system, the training module 1120 may train the ODT resistance based on time domain reflectometry (TDR) of a reflection signal received from the second interface circuit 1210. For example, the training module 1120 may determine a position of a termination of the second interface circuit 1210 based on the TDR of the reflection signal and may train the ODT resistance for impedance matching in the second interface circuit 1210 (or to minimize impedance discontinuity).

That is, the training module 1120 may determine positions (discontinuous positions), at which an impedance value (or a voltage level) in the second interface circuit 1210 sharply changes, based on the TDR of the reflection signal and may train the ODT resistance based on the impedance values (or voltage levels) of the determined positions; in this case, the impedance matching may be performed at the less number of times of training.

In some embodiments, the training module 1120 may include a plurality of hardware for performing the functions. For example, the training module 1120 may include a field-programmable gate array (FPGA), an application specific integrated circuit (ASIC), a processor, and/or the like.

The non-volatile memory device 1200 may store data under control of the storage controller 1100. In some embodiments, the non-volatile memory device 1200 may be a NAND flash memory device, but the present disclosure is not limited thereto. For example, the non-volatile memory device 1200 may be one of various storage devices, which retain data stored therein even when a power is turned off, such as a phase-change random access memory (PRAM), a magnetic random access memory (MRAM), a resistive random access memory (RRAM), and a ferroelectric random access memory (FRAM).

The non-volatile memory device 1200 may include the second interface circuit 1210 and a memory die 1220. The second interface circuit 1210 may transmit data read from the non-volatile memory device 1200 to the storage controller 1100 or may receive data to be stored in the non-volatile memory device 1200 from the storage controller 1100. The second interface circuit 1210 may be implemented to comply with the standard protocol such as Toggle or ONFI.

The second interface circuit 1210 may be connected to the first interface circuit 1110 of the storage controller 1100 through the channel. The first interface circuit 1110, the channel, and the second interface circuit 1210 may have different impedance values or different resistance values. In this case, data or signals transmitted/received through the first interface circuit 1110, the channel, and the second interface circuit 1210 may be reflected.

The memory die 1220 may store data. For example, the memory die 1220 may store data received from the storage controller 1100. Also, the memory die 1220 may read data based on a read request of the storage controller 1100 and may provide the read data to the storage controller 1100. The memory die 1220 may include a plurality of memory cells and may store data in the plurality of memory cells.

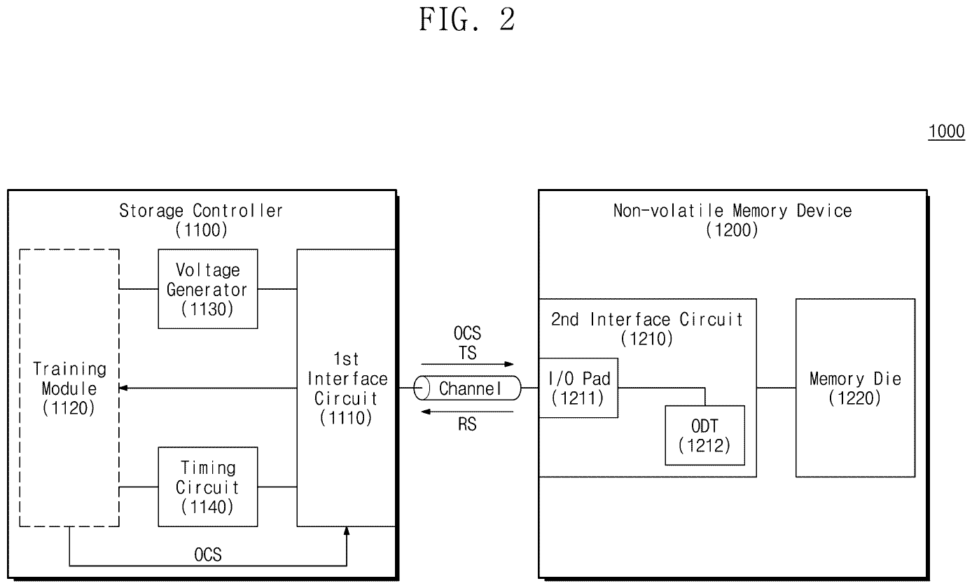

FIG. 2 is a block diagram illustrating a storage system of FIG. 1 in more detail, according to some embodiments of the present disclosure. Referring to FIG. 2, the storage system 1000 may include the storage controller 1100 and the non-volatile memory device 1200.

The storage controller 1100 may perform impedance matching with the non-volatile memory device 1200. For example, the storage controller 1100 may perform the TDR on the reflection signal received from the non-volatile memory device 1200 and may perform impedance matching with the non-volatile memory device 1200 based on an execution result of the TDR.

In some embodiments, the storage controller 1100 may provide a test signal TS to the non-volatile memory device 1200. The test signal TS may be a step signal or a pulse signal, which has one voltage level. The storage controller 1100 may provide the test signal TS to the non-volatile memory device 1200 and may receive a reflection signal RS from the non-volatile memory device 1200. The reflection signal RS may be generated as the test signal TS is reflected in the non-volatile memory device 1200. The reflection signal RS may be generated as the test signal TS is reflected in the non-volatile memory device 1200 not impedance-matched.

The storage controller 1100 may include the first interface circuit 1110, the training module 1120, a voltage generator 1130, and a timing circuit 1140. The first interface circuit 1110 may be connected to the non-volatile memory device 1200. For example, the first interface circuit 1110 may be connected (e.g., communicatively coupled) to the second interface circuit 1210 of the non-volatile memory device 1200 through the channel and may communicate with the second interface circuit 1210. In other words, the storage controller 1100 is configured to communicate with the non-volatile memory device 1200.

The first interface circuit 1110, the channel, and the second interface circuit 1210 may have different impedances. Accordingly, before the impedance matching is performed, a signal transmitted/received through the first interface circuit 1110, the channel, and the second interface circuit 1210 may experience reflection. The reflection may cause the distortion of the signal.

In some embodiments, the first interface circuit 1110 may provide the test signal TS to the second interface circuit 1210 and may receive the reflection signal RS. For example, the first interface circuit 1110 may generate the test signal TS and may provide the test signal TS to the second interface circuit 1210 through the channel. The test signal TS may be reflected in the second interface circuit 1210. The first interface circuit 1110 may receive, from the second interface circuit 1210, the reflection signal RS generated when the test signal TS is reflected. In some embodiments, the first interface circuit 1110 may provide a plurality of test signals (e.g., a first test signal, a second test signal, a third test signal, etc.) to the second interface circuit 1210.

In some embodiments, the first interface circuit 1110 may receive the reflection signal RS from the second interface circuit 1210 in a state where the non-volatile memory device 1200 is not turned on. For example, the reflection signal RS may be generated only by the reflection of the test signal TS caused because the impedances of the first interface circuit 1110, the channel, and the second interface circuit 1210 are not matched and may not be generated by the operation of the second interface circuit 1210.

In some embodiments, the first interface circuit 1110 may provide an ODT control signal OCS to the second interface circuit 1210. For example, the first interface circuit 1110 may receive the ODT control signal OCS from the training module 1120 and may transmit the received ODT control signal OCS to the second interface circuit 1210. The ODT control signal OCS may be used to control an ODT resistance 1212 of the non-volatile memory device 1200. The ODT control signal OCS will be described in further detail later.

The training module 1120 may generate the ODT control signal OCS for controlling the ODT resistance 1212. For example, to perform impedance matching of the second interface circuit 1210, the training module 1120 may determine a resistance value of the ODT resistance 1212 and may generate the ODT control signal OCS indicating the determined resistance value. The training module 1120 may provide the generated ODT control signal OCS to the second interface circuit 1210 through the first interface circuit 1110.

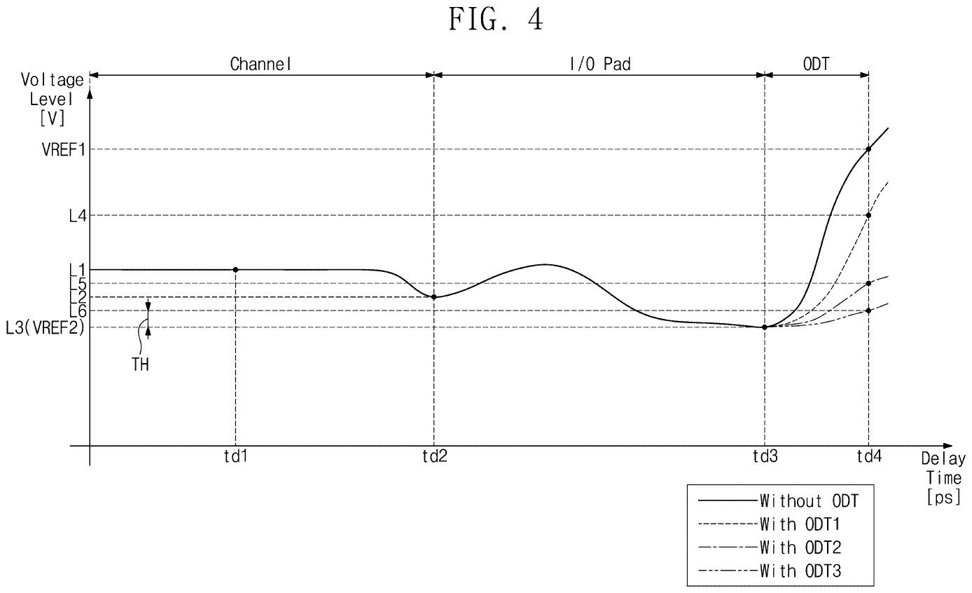

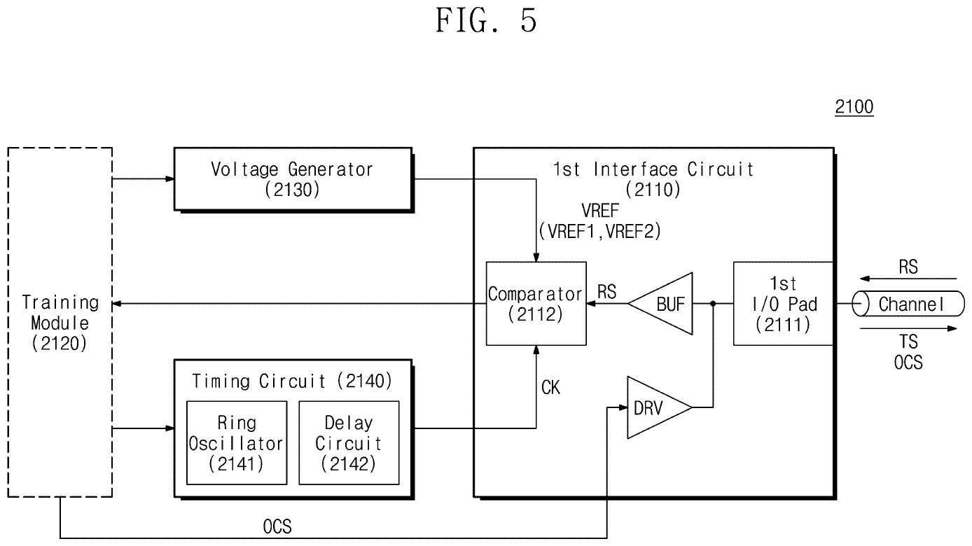

In some embodiments, the training module 1120 may determine the resistance value of the ODT resistance 1212 based on the TDR of the reflection signal RS. For example, the training module 1120 may determine the resistance value of the ODT resistance 1212 such that the resistance value of the ODT resistance 1212 is identical or similar to a resistance value of the channel or an I/O pad 1211. The training module 1120 will be described in further detail with reference to FIGS. 4 and 5.

The voltage generator 1130 may generate a voltage having various voltage levels. For example, the voltage generator 1130 may generate a voltage having various voltage levels (e.g., a reference voltage level) for comparison with voltages of sampling signals obtained by sampling the reflection signal RS at the first interface circuit 1110. In some embodiments, the voltage generator 1130 may generate a voltage having a first reference voltage level and a second reference voltage level. The voltage generator 1130 may provide the first interface circuit 1110 with the voltage having various voltage levels. In some embodiments, the voltage generator 1130 may generate the voltage under control of the training module 1120 and may provide the generated voltage to the first interface circuit 1110. The voltage generator 1130 will be described in further detail with reference to FIGS. 4 and 5.

The first interface circuit 1110 may sample the reflection signal RS. For example, the first interface circuit 1110 may detect the sampling signals by sampling the reflection signal RS received from the second interface circuit 1210 through the channel.

The first interface circuit 1110 may perform comparison operations on the voltage having various voltage levels (e.g., a reference voltage level) received from the voltage generator 1130 and the sampling signals. The first interface circuit 1110 may provide a result of the comparison operations to the training module 1120.

In some embodiments, the first interface circuit 1110 may sample the reflection signal RS at various times. For example, the first interface circuit 1110 may sample the reflection signal RS at respective time points at which various delay times elapse from a time point at which the test signal TS is provided to the second interface circuit 1210. The first interface circuit 1110 may sample the reflection signal RS at respective time points at which various delay times elapse, based on clock information or delay information received from the timing circuit 1140.

Various times may indicate various distance or positions from the first interface circuit 1110. Because the speed of the test signal TS or the reflection signal RS is uniform, a moving time of the test signal TS or the reflection signal RS may be proportional to the moving distance of the test signal TS or the reflection signal RS. That is, when the test signal TS or the reflection signal RS moves during a longer time, the moving distance of the test signal TS or the reflection signal RS may become longer.

For example, after the first interface circuit 1110 provides the test signal TS to the second interface circuit 1210, when the first interface circuit 1110 detects first and second sampling signals by sampling the reflection signal RS at respective time points at which first and second delay times elapse, the first and second sampling signals may correspond to resistances of different positions in the channel or the second interface circuit 1210. Accordingly, the delay time may indicate a position in the channel or the second interface circuit 1210. This will be described in further detail with reference to FIG. 4.

The timing circuit 1140 may provide the first interface circuit 1110 with the clock information or the delay information indicating various delay times. In other words, the timing circuit 1140 may provide a time signal indicating various delay times to the first interface circuit 1110. For example, the timing circuit 1140 may determine whether the first interface circuit 1110 samples the reflection signal RS, at any time after the first interface circuit 1110 provides the test signal TS to the second interface circuit 1210. The timing circuit 1140 will be described in further detail with reference to FIG. 5.

The non-volatile memory device 1200 may include the second interface circuit 1210 and the memory die 1220. The second interface circuit 1210 may be connected to the first interface circuit 1110. For example, the second interface circuit 1210 may be connected to the first interface circuit 1110 through the channel and may transmit/receive data to/from the first interface circuit 1110.

The second interface circuit 1210 may include the input/output (I/O) pad 1211 and the ODT resistance 1212. The I/O pad 1211 may output data or a signal to the first interface circuit 1110 through the channel or may receive data or a signal from the first interface circuit 1110. The I/O pad 1211 may transfer the data or the signal received from the first interface circuit 1110 to the memory die 1220.

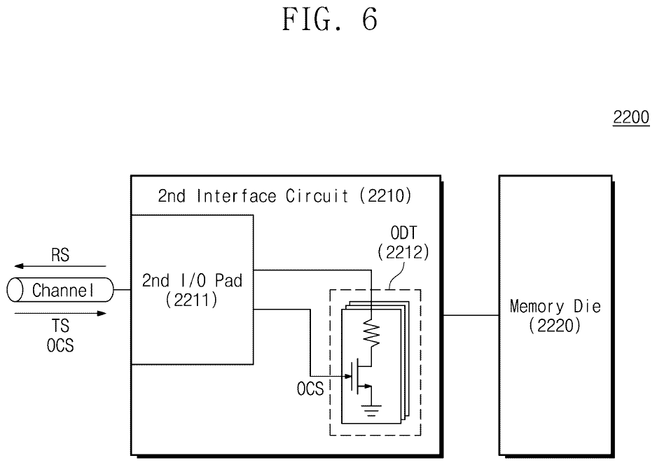

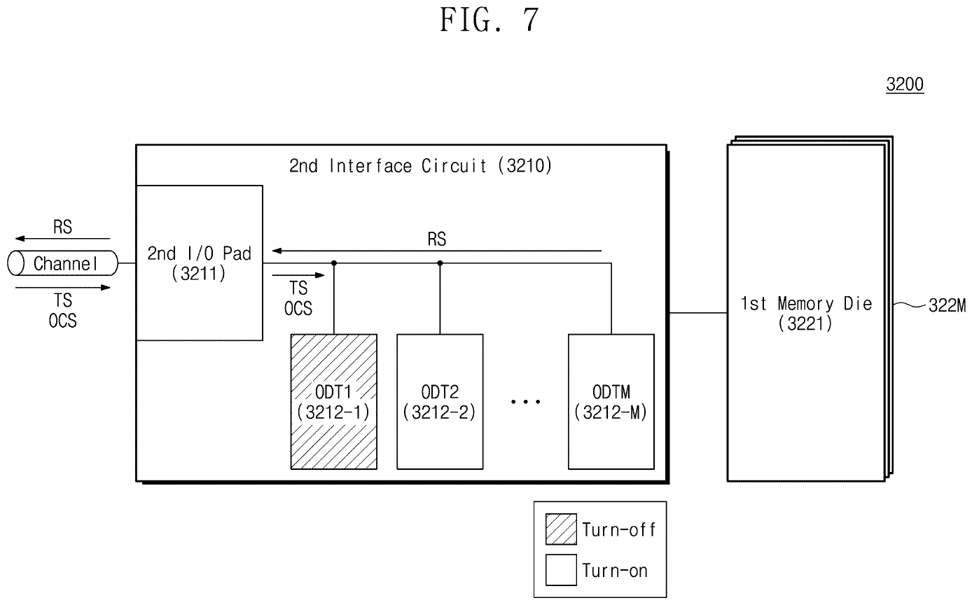

The ODT resistance 1212 may be a variable resistance connected to the termination of the second interface circuit 1210. For example, the ODT resistance 1212 may have various resistance values to be used for impedance matching of the second interface circuit 1210. In some embodiments, the ODT resistance 1212 may have a resistance value based on the ODT control signal OCS received from the storage controller 1100. The ODT resistance will be described in further detail with reference to FIGS. 6 and 7.

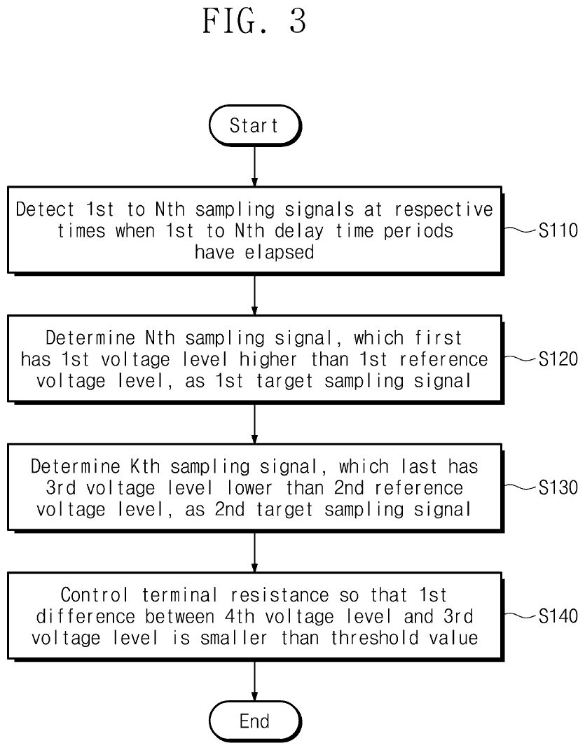

FIG. 3 is a flowchart illustrating an operating method of a storage controller according to some embodiments of the present disclosure. Referring to FIGS. 2 and 3, the storage controller 1100 may control the ODT resistance 1212 for impedance matching of the second interface circuit 1210.

In operation S110, the storage controller 1100 may detect first to N-th sampling signals at respective time points at which first to N-th delay times sequentially elapse. For example, after the storage controller 1100 or the first interface circuit 1110 provides a first test signal to the second interface circuit 1210, the storage controller 1100 or the first interface circuit 1110 may detect the first to N-th sampling signals respectively at time points at which the first to N-th delay times sequentially elapse. For example, the first to N-th delay times may be sequentially delayed by one clock period or less (i.e., by as much as one clock period).

In some embodiments, after the first interface circuit 1110 provides the first test signal to the second interface circuit 1210, a first reflection signal may be generated by the reflection of the first test signal. The first interface circuit 1110 may detect the first to N-th sampling signals having voltages proportional to resistances of first to N-th positions in the channel or the second interface circuit 1210 corresponding to the first to N-th delay times. For example, the storage controller 1100 (or the first interface circuit 1110) may detect the first to N-th sampling signals by sampling the first reflection signal at the respective time points at which the first to N-th delay times sequentially elapse.

In operation S120, the storage controller 1100 may determine the N-th sampling signal having a first voltage level higher than a first reference voltage level as a first target sampling signal. For example, the storage controller 1100 or the first interface circuit 1110 may sequentially perform comparison operations on the first reference voltage level and the first to N-th sampling signals and may determine that the N-th sampling signal has the first voltage level higher than the first reference voltage level, based on a result of the comparison operations. For example, the storage controller 1100 (or the first interface circuit 1110) may sequentially perform comparison operations on respective voltage levels of the first to N-th sampling signals and the first reference voltage level. In some embodiments, the training module 1120 may determine that the first voltage level of the N-th sampling signal is higher than the first reference voltage level, in response to a result of the comparison operations. The first reference voltage level may have an arbitrary value (e.g., a predetermined value) between a voltage level of the first test signal and two times the voltage level of the first test signal. For example, the first reference voltage level may be higher than the voltage level of the first test signal and may be lower than two times the voltage level of the first test signal. The first reference voltage level will be described in further detail with reference to FIG. 4.

That is, the N-th position corresponding to the N-th sampling signal may indicate the termination (at which the ODT resistance 1212 is placed) at which a resistance value sharply increases in the second interface circuit 1210. “N” is an arbitrary integer of 1 or more.

In some embodiments, the first interface circuit 1110 may provide the training module 1120 with a result of the comparison operations of the first reference voltage level and the first to N-th sampling signals.

In operation S130, the storage controller 1100 may determine the K-th sampling signal last having a third voltage level lower than a second reference voltage level as a second target sampling signal. For example, the storage controller 1100 or the first interface circuit 1110 may determine the K-th sampling signal last having the third voltage level lower than the second reference voltage level from among the first to N-th sampling signals as the second target sampling signal. The second reference voltage level may have a voltage level at which a voltage level starts to monotonously increase to the first reference voltage level. For example, the second reference voltage level may be lower than the first reference voltage level. The second reference voltage level will be described in further detail with reference to FIG. 4.

That is, the K-th position corresponding to the K-th sampling signal may indicate the I/O pad 1211 closer to the first interface circuit 1110 than the position of the termination at which the resistance value sharply increases. “K” is an arbitrary integer greater than 1 and smaller than “N”. That is, “N” is an integer greater than “K”.

In some embodiments, the storage controller 1100 may perform a comparison operation on the third voltage level and a first test voltage level. The storage controller 1100 may decrease the first test voltage level to a second test voltage level in response to determining that the third voltage level is lower than or equal to (i.e., is not higher than) the first test voltage level. The second test voltage level may be lower than the first test voltage level. The storage controller 1100 may perform a comparison operation on the third voltage level and the second test voltage level. The storage controller 1100 may perform a comparison operation on a voltage level of a (K−1)-th sampling signal, from among the first to N-th sampling signals, and the third voltage level in response to determining that the third voltage level is higher than the second test voltage level. The storage controller 1100 may determine the K-th sampling signal as the second target sampling signal in response to determining that the voltage level of the (K−1)-th sampling signal is higher than the third voltage level. In some embodiments, the storage controller 1100 may determine the first test voltage level as the second reference voltage level.

In some embodiments, the storage controller 1100 may perform a comparison operation on a voltage level of a (K+1)-th sampling signal, from among the first to N-th sampling signals, and the first test voltage level. The storage controller 1100 may perform a comparison operation on the third voltage level of the K-th sampling signal and the voltage level of the (K+1)-th sampling signal in response to determining that the voltage level of the (K+1)-th sampling signal is higher than the first test voltage level. The storage controller 1100 may perform the comparison operation described above on the third voltage level and the first test voltage level in response to determining that the voltage level of the (K+1)-th sampling signal is lower than or equal to (i.e., is not higher than) the third voltage level.

In operation S140, the storage controller 1100 may control the ODT resistance 1212 such that a first difference between a fourth voltage level of a third target sampling signal and the third voltage level is smaller than a threshold value.

For example, the storage controller 1100 or the training module 1120 may control the ODT resistance 1212 such that the fourth voltage level (e.g., a resistance value at the position of the ODT resistance 1212) at a time point at which the N-th delay time elapses (i.e., at the position corresponding to the ODT resistance 1212 located at the termination of the second interface circuit 1210) is identical or similar to the third voltage level (e.g., a resistance value of the I/O pad 1211) at a time point at which the K-th delay time elapses (i.e., at the position of the I/O pad 1211 of the second interface circuit 1210). For example, after the storage controller 1100 (or the first interface circuit 1110) provides a second test signal to the non-volatile memory device 1200 (e.g., to the second interface circuit 1210), the storage controller 1100 (or the training module 1120) may control the ODT resistance 1212 such that the first difference between the fourth voltage level of the third target sampling signal and the third voltage level is smaller than the threshold value. For example, the third target sampling signal may be detected at a time point at which the N-th delay time elapses.

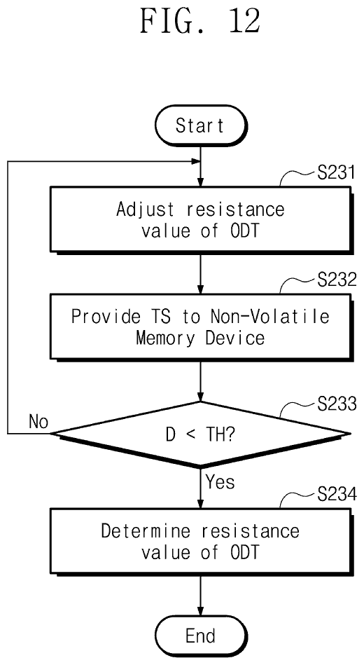

In some embodiments, the training module 1120 may provide the ODT resistance 1212 with the ODT control signal OCS for changing the resistance value of the ODT resistance 1212 to an arbitrary value and may then determine whether the first difference between the third and fourth voltage levels is smaller than the threshold value. For example, the storage controller 1100 may execute the training module 1120 such that the training module 1120 may control the ODT resistance 1212 (e.g., with the ODT control signal OCS) based on the voltage level of the first test signal and the third voltage level. The storage controller 1100 (or the training module 1120) may determine a final value (i.e., a final resistance value) of the ODT resistance 1212 at which the first difference between the fourth voltage level and the third voltage level is smaller than the threshold value, based on the training module 1120. The storage controller 1100 (or the training module 1120) may control the ODT resistance 1212 based on the final value of the ODT resistance 1212 that was determined. For example, the storage controller 1100 (or the training module 1120) may generate the ODT control signal OCS based on the final value of the ODT resistance 1212 that was determined, and may provide the ODT control signal OCS to the non-volatile memory device 1200 (e.g., to the second interface circuit 1210). When it is determined that the first difference is greater than the threshold value, the training module 1120 may provide the ODT control signal OCS to the ODT resistance 1212 to change the resistance value of the ODT resistance 1212 to another arbitrary value. The training module 1120 will be described in further detail with reference to FIGS. 5 and 12.

In some embodiments, the storage controller 1100 (or the training module 1120) may control the ODT resistance 1212 such that the ODT resistance 1212 has a first value (i.e., a first resistance value). After providing the second test signal to the non-volatile memory device 1200 (e.g., to the second interface circuit 1210), the storage controller 1100 may detect the third target sampling signal at a time point at which the N-th delay time elapses. The storage controller 1100 may determine whether the first difference between the fourth voltage level of the third target sampling signal and the third voltage level is smaller than the threshold value. The storage controller 1100 (or the first interface circuit 1110) may determine the first value as the final value of the ODT resistance 1212 in response to determining that the first difference is smaller than the threshold value.

In some embodiments, the storage controller 1100 may control the ODT resistance 1212 such that the ODT resistance 1212 has a second value (i.e., a second resistance value). After providing a third test signal to the non-volatile memory device 1200 (e.g., to the second interface circuit 1210), the storage controller 1100 may detect a fourth target sampling signal at a time point at which the N-th delay time elapses. The storage controller 1100 may determine whether a second difference between a voltage level of the fourth target sampling signal and the third voltage level is smaller than the threshold value. In response to determining that the second difference is greater than or equal to (i.e., is not smaller than) the threshold value, the storage controller 1100 may control the ODT resistance 1212 such that the ODT resistance 1212 has the first value, as described above.

That is, the training module 1120 may perform impedance matching by controlling the ODT resistance 1212 such that the resistance value at the termination of the second interface circuit 1210 is identical or similar to the resistance value of the I/O pad 1211 and may minimize the distortion of the data or signal transmitted/received between the first and second interface circuits 1110 and 1210.

FIG. 4 is a graph illustrating a change in a voltage level according to some embodiments of the present disclosure. Referring to FIGS. 2 and 4, the first interface circuit 1110 may provide the test signal TS to the second interface circuit 1210 and may then detect sampling signals by sampling the reflection signal RS at time points at which various delay times elapse. The first interface circuit 1110 may compare first and second reference voltage levels VREF1 and VREF2 and voltages of the sampling signals and may determine positions of the termination of the second interface circuit 1210 and the I/O pad 1211.

The training module 1120 may perform impedance matching by adjusting the resistance value of the ODT resistance 1212 based on a result of comparison operations of the first interface circuit 1110.

In FIG. 4, the horizontal axis represents a delay time, and the vertical axis represents a voltage level. A solid line indicates a voltage level of the reflection signal RS (or voltage levels of sampling signals) when the ODT resistance 1212 is not turned on (i.e., without ODT). A dotted line indicates a voltage level of the reflection signal RS (or voltage levels of sampling signals) when the ODT resistance 1212 has a first resistance value (i.e., with ODT1). A dash-single dotted line indicates a voltage level of the reflection signal RS (or voltage levels of sampling signals) when the ODT resistance 1212 has a second resistance value (i.e., with ODT2). A dash-double dotted line indicates a voltage level of the reflection signal RS (or voltage levels of sampling signals) when the ODT resistance 1212 has a third resistance value (i.e., with ODT3).

At a first delay time td1, the sampling signal may have a first voltage level L1. The first delay time td1 may correspond to a position in the channel. The reflection signal RS or the sampling signal may have a voltage level identical or similar to the first voltage level L1 in the channel.

At a second delay time td2, the sampling signal may have a second voltage level L2 lower than the first voltage level L1. The second delay time td2 may correspond to a position at an intermediate point between the channel and the second interface circuit 1210. A resistance value or an impedance value of the reflection signal RS or the sampling signal may be decreased by the resistance difference of the channel and the second interface circuit 1210 or a parasitic capacitance between the channel and the second interface circuit 1210. Accordingly, the voltage level of the sampling signal proportional to the resistance value or the impedance value may decrease.

The voltage level of the reflection signal RS or the sampling signal may sharply increase between a third delay time td3 and a fourth delay time td4. In particular, when the ODT resistance 1212 is turned off, the voltage level of the reflection signal RS or the sampling signal may sharply increase from a third voltage level L3 to a fourth voltage level L4 during a time period from td3 to td4.

A time period from td2 to td3 may correspond to the position of the I/O pad 1211. The third delay time td3 may correspond to a position between the I/O pad 1211 and the termination of the second interface circuit 1210. Because the termination of the second interface circuit 1210 is opened, the resistance value may sharply increase from the third delay time td3. This may mean that the voltage level of the reflection signal RS or the sampling signal sharply increases.

In some embodiments, the first interface circuit 1110 may sequentially sample the reflection signal RS at various delay times and may perform the comparison operations on voltage levels of the sampled sampling signals and the first reference voltage level VREF1. In response to determining that the voltage level of the reflection signal RS exceeds the first reference voltage level VREF1 at the fourth delay time td4, the first interface circuit 1110 may determine the sampling signal detected at the fourth delay time td4 as a first target sampling signal. The first interface circuit 1110 may provide a result of performing the comparison operations to the training module 1120.

That is, the training module 1120 may determine that a position corresponding to the fourth delay time td4 indicates the termination of the second interface circuit 1210.

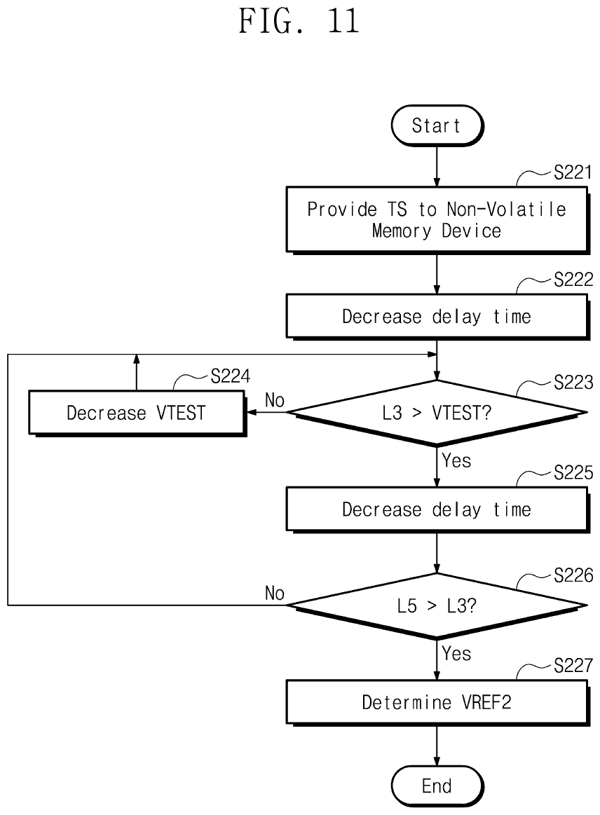

In some embodiments, the first interface circuit 1110 may determine an inflection point (i.e., a point between the position of the I/O pad 1211 and the position of the ODT resistance 1212) at which the monotonous increase of the voltage level from the third voltage level L3 at the third delay time td3 to the first reference voltage level VREF1 at the fourth delay time td4 starts. For example, the first interface circuit 1110 may determine whether the voltage level of the reflection signal RS also decreases, by gradually shortening a delay time from the fourth delay time td4. When the voltage level of the reflection signal RS does not decrease even though the delay time is shortened, the first interface circuit 1110 may determine the shortened delay time (i.e., the third delay time td3) as the inflection point. This will be described in further detail with reference to FIG. 11. The first interface circuit 1110 may provide the result of performing the comparison operations to the training module 1120.

In some embodiments, the training module 1120 may control the ODT resistance 1212 to allow a difference between the voltage level at the third delay time td3 and the voltage level at the fourth delay time td4 to be smaller than a threshold value TH. For example, the training module 1120 may provide the ODT control signal OCS to the ODT resistance 1212 such that the ODT resistance 1212 has an arbitrary resistance value.

In some embodiments, the training module 1120 may control the ODT resistance 1212 such that the ODT resistance 1212 has a first resistance value ODT1. After the ODT resistance 1212 is controlled, in response to determining that the voltage level at the fourth delay time td4 is the fourth voltage level L4 and the difference is greater than the threshold value TH, the training module 1120 may control the ODT resistance 1212 such that the ODT resistance 1212 has a second resistance value ODT2 different from the first resistance value ODT1.

As described above, until the difference between the voltage level at the third delay time td3 and the voltage level at the fourth delay time td4 is smaller than the threshold value TH, the training module 1120 may control the ODT resistance 1212 such that the ODT resistance 1212 has various resistance values.

In some embodiments, when the ODT resistance 1212 has a third resistance value ODT3, a difference between the third voltage level L3 at the third delay time td3 and a sixth voltage level L6 at the fourth delay time td4 may be smaller than or equal to the threshold value TH. For impedance matching of the second interface circuit 1210, the training module 1120 may determine the third resistance value ODT3 as the resistance value of the ODT resistance 1212.

FIG. 5 is a block diagram illustrating a storage controller according to some embodiments of the present disclosure. Referring to FIG. 5, a storage controller 2100 may include a first interface circuit 2110, a training module 2120, a voltage generator 2130, and a timing circuit 2140. The first interface circuit 2110, the training module 2120, the voltage generator 2130, and the timing circuit 2140 are partially similar to the first interface circuit 1110, the training module 1120, the voltage generator 1130, and the timing circuit 1140 of FIG. 2. Below, repeated descriptions may be omitted to avoid redundancy.

The first interface circuit 2110 may include a first I/O pad 2111, a comparator 2112, a buffer BUF, and an output driver DRV. The first I/O pad 2111 may output or receive data or a signal through the channel. The first I/O pad 2111 may store the data or the signal received through the channel in the buffer BUF or may transfer the data or the signal to the comparator 2112.

The comparator 2112 may perform the comparison operations on voltage levels of sampling signals detected by sampling the reflection signal RS at various delay times and a reference voltage level VREF. In some embodiments, the comparator 2112 may receive the reflection signal RS from the channel through the buffer BUF, may receive a voltage having the reference voltage level VREF from the voltage generator 2130, and may receive time information CK from the timing circuit 2140. The comparator 2112 may perform the comparison operations based on the reflection signal RS, the reference voltage level VREF, and the time information CK. The comparator 2112 may provide a result of the comparison operations to the training module 2120.

The buffer BUF may store the data or the signal received from the channel. For example, the buffer BUF may store the reflection signal RS received through the channel. The buffer BUF may provide the stored reflection signal RS to the comparator 2112.

The output driver DRV may generate the test signal TS. For example, the output driver DRV may generate the test signal TS and may output the generated test signal TS to the channel through the first I/O pad 2111. Also, the output driver DRV may output the ODT control signal OCS received from the training module 2120 to the channel through the first I/O pad 2111.

The voltage generator 2130 may provide the comparator 2112 with a voltage having various reference voltage levels VREF (e.g., the first and second reference voltage levels VREF1 and VREF2). In some embodiments, the voltage generator 2130 may generate the reference voltage level VREF under control of the training module 2120.

The timing circuit 2140 may include a ring oscillator 2141 and a delay circuit 2142. The ring oscillator 2141 may generate a period signal having a uniform period. The delay circuit 2142 may delay a phase of the period signal. The timing circuit 2140 may generate the time information CK (i.e., a time signal) indicating various delay times which are obtained by delaying the period signal as much as an integer multiple of the period or delaying the period signal within one period. The timing circuit 2140 may provide the time information CK to the comparator 2112.

FIG. 6 is a diagram illustrating a non-volatile memory device according to some embodiments of the present disclosure. Referring to FIG. 6, a non-volatile memory device 2200 may include a second interface circuit 2210 and a memory die 2220. The second interface circuit 2210 and the memory die 2220 are partially similar to the second interface circuit 1210 and the memory die 1220 of FIGS. 1 and 2. Below, repeated descriptions may be omitted to avoid redundancy.

The second interface circuit 2210 may include a second I/O pad 2211 and an ODT resistance 2212. The second I/O pad 2211 and the ODT resistance 2212 may be similar to the I/O pad 1211 and the ODT resistance 1212 of FIG. 2.

The second I/O pad 2211 may output or receive data or a signal through the channel. The second I/O pad 2211 may transfer the ODT control signal OCS received through the channel to the ODT resistance 2212.

The ODT resistance 2212 may include a plurality of resistance elements (i.e., resistive elements) and a plurality of transistors. The plurality of resistance elements may respectively correspond to the plurality of transistors. In the plurality of resistance elements and the plurality of transistors, one resistance element and one transistor corresponding to each other may form a pair. The plurality of transistors may be turned on or turned off based on the ODT control signal OCS.

The ODT resistance 2212 may be a variable resistance. For example, the ODT resistance 2212 may have various resistance values based on the ODT control signal OCS. In more detail, as the plurality of transistors of the ODT resistance 2212 are turned on or turned off based on the ODT control signal OCS, the ODT resistance 2212 may have various resistance values.

The ODT resistance 2212 may be located at the termination of the second interface circuit 2210. As described above with reference to FIG. 4, when the ODT resistance 2212 is turned off, the impedance at the termination of the second interface circuit 2210 may sharply increase compared to the impedance of the second I/O pad 2211. The ODT resistance 2212 may be used for impedance matching of the second interface circuit 2210. As the impedance matching is performed by the ODT resistance 2212, the distortion of data or signals which are transmitted/received may be minimized in the second interface circuit 2210.

FIG. 7 is a diagram illustrating a non-volatile memory device according to some embodiments of the present disclosure. Referring to FIG. 7, a non-volatile memory device 3200 may include a second interface circuit 3210 and a plurality of memory dies 3221 to 322M. The second interface circuit 3210 and the plurality of memory dies 3221 to 322M are partially similar to the second interface circuits 1210 and 2210 and the memory dies 1220 and 2220 of FIGS. 2 and 6. Below, repeated descriptions may be omitted to avoid redundancy. “M” is an integer greater than 1.

The second interface circuit 3210 may include a plurality of ODT resistances 3212-1 to 3212-M. As used herein, the plurality of ODT resistances 3212-1 to 3212-M may also be referred to as first to M-th ODT resistances. The plurality of ODT resistances 3212-1 to 3212-M may have the same resistance value or different resistance values and may be turned on or turned off independently of each other. For example, the plurality of ODT resistances 3212-1 to 3212-M may be turned on based on the ODT control signal OCS to have resistance values independently of each other.

For example, the first ODT resistance 3212-1 may be turned off based on the ODT control signal OCS, and the remaining ODT resistances 3212-2 to 3212-M may be turned on based on the ODT control signal OCS. The plurality of ODT resistances 3212-1 to 3212-M may be used for impedance matching of the second interface circuit 3210 based on the ODT control signal OCS.

The plurality of ODT resistances 3212-1 to 3212-M may be respectively connected to the plurality of memory dies 3221 to 322M. For example, the plurality of ODT resistances 3212-1 to 3212-M may be respectively connected to the memory dies 3221 to 322M at the termination of the second interface circuit 3210.

In some embodiments, distances from a second I/O pad 3211 to the plurality of ODT resistances 3212-1 to 3212-M may be different from each other. In some embodiments, the M-th ODT resistance 3212-M among the plurality of ODT resistances 3212-1 to 3212-M may be located at a position the most distant from the second interface circuit 3210 (or the second I/O pad 3211). For impedance matching, the storage controllers 1100 and 2100 of FIGS. 2 and 5 may control the plurality of ODT resistances 3212-1 to 3212-M while turning on or off the ODT resistances starting from the M-th ODT resistance 3212-M located at the most distant position. In some embodiments, turning on or off the ODT resistance indicates turning on or off the transistor of which one end is connected to the ODT resistance (e.g., the opposite end of the transistor may be connected to the ground (i.e., a reference voltage)).

In some embodiments, the storage controllers 1100 and 2100 of FIGS. 2 and 5 may control ones of ODT resistances (i.e., at least some ODT resistances) among the plurality of ODT resistances 3212-1 to 3212-M such that the ones of the ODT resistances have second to L-th values. After providing a test signal TS (e.g., a second test signal) to the non-volatile memory device 3200 (e.g., to the second interface circuit 3210), the storage controllers 1100 and 2100 of FIGS. 2 and 5 may detect a third target sampling signal at a time point at which an N-th delay time elapses. The storage controllers 1100 and 2100 of FIGS. 2 and 5 may determine whether a first difference between a fourth voltage level of the third target sampling signal and a third voltage level of a K-th sampling signal, from among first to N-th sampling signals, is smaller than a threshold value. The storage controllers 1100 and 2100 of FIGS. 2 and 5 may determine the second to L-th values as a final value of the plurality of ODT resistances 3212-1 to 3212-M in response to determining that the first difference is smaller than the threshold value. “L” is an integer greater than 1 and smaller than “M”. That is, “M” is an integer greater than “L”.

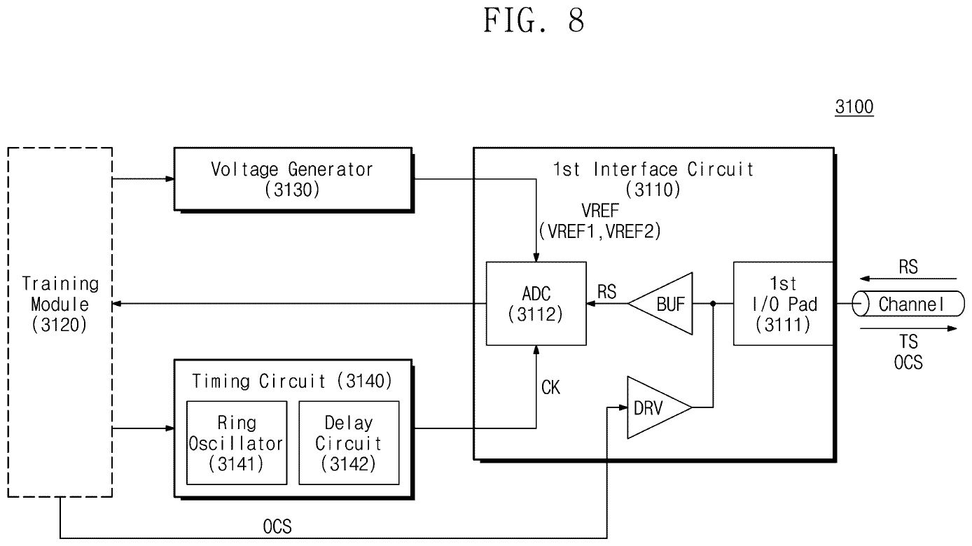

FIG. 8 is a diagram illustrating a storage controller according to some embodiments of the present disclosure. Referring to FIG. 8, a storage controller 3100 may include a first interface circuit 3110, a training module 3120, a voltage generator 3130, and a timing circuit 3140. The first interface circuit 3110, the training module 3120, the voltage generator 3130, and the timing circuit 3140 are partially similar to the first interface circuits 1110 and 2110, the training modules 1120 and 2120, the voltage generators 1130 and 2130, and the timing circuits 1140 and 2140 of FIGS. 2 and 5. Below, repeated descriptions may be omitted to avoid redundancy.

The first interface circuit 3110 may include a first I/O pad 3111, an analog-to-digital converter (ADC) 3112, the buffer BUF, and a driver DRV. In FIG. 8, the ADC 3112 is illustrated as being separated from the buffer BUF, but the present disclosure is not limited thereto. The ADC 3112 may operate together with the buffer BUF or may operate without the buffer BUF.

The ADC 3112 may sample the reflection signal RS at high speed to detect sampling signals. For example, the ADC 3112 may sample various voltage levels of the reflection signal RS at high speed and may perform the comparison operations on voltage levels of the sampling signals and the reference voltage level (e.g., the first or second reference voltage level VREF1 or VREF2 of FIGS. 5 and 8). The ADC 3112 may provide a result of the comparison operations to the training module 3120.

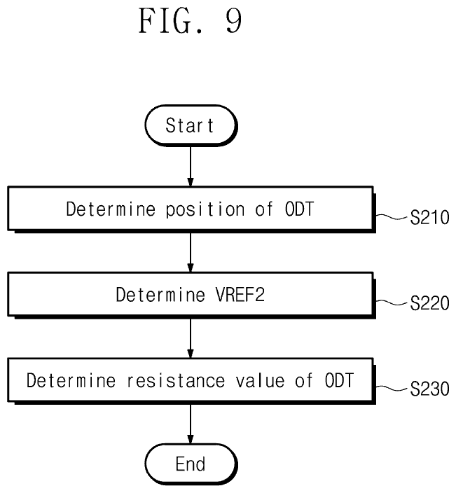

FIG. 9 is a flowchart illustrating an operating method of a storage controller according to some embodiments of the present disclosure. Referring to FIGS. 2 and 9, the storage controller 1100 may determine a resistance value of the ODT resistance 1212 to perform impedance matching at the termination of the second interface circuit 1210.

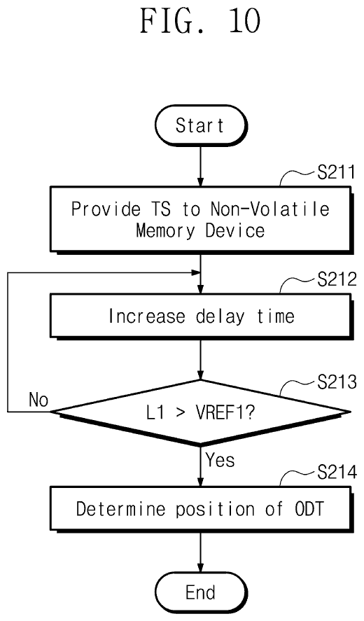

In operation S210, the storage controller 1100 may determine a position of the ODT resistance 1212. For example, the storage controller 1100 may determine a delay time at which the voltage level of the reflection signal RS sharply increases, that is, is greater than the first reference voltage level VREF1 after the test signal TS is provided to the second interface circuit 1210 and may determine a position of the ODT resistance 1212 placed at the termination of the second interface circuit 1210 based on the determined delay time. This will be described in further detail with reference to FIG. 10.

In operation S220, the storage controller 1100 may determine the second reference voltage level VREF2. For example, the storage controller 1100 may determine a delay time at which the voltage level of the reflection signal RS starts to sharply increase and may determine a voltage level at a time point at which the determined delay time elapses, as the second reference voltage level VREF2. This will be described in further detail with reference to FIG. 11.

In operation S230, the storage controller 1100 may determine the resistance value of the ODT resistance 1212. For example, the storage controller 1100 may determine the resistance value of the ODT resistance 1212 such that the voltage level of the reflection signal RS corresponding to the resistance value of the ODT resistance 1212 placed at the termination of the second interface circuit 1210 is identical or similar to the second reference voltage level VREF2. This will be described in further detail with reference to FIG. 12.

FIG. 10 is a flowchart illustrating an operating method of a storage controller according to some embodiments of the present disclosure. Referring to FIGS. 2 and 10, the storage controller 1100 may determine a position of the ODT resistance 1212. Operation S211 to operation S214 may constitute a portion of operation S210 of FIG. 9.

In operation S211, the storage controller 1100 may provide the test signal TS to the non-volatile memory device 1200. The test signal TS may be a step signal or a pulse signal, which has a uniform voltage level. The test signal TS may be reflected in the channel and the non-volatile memory device 1200 (e.g., the second interface circuit 1210). The storage controller 1100 or the first interface circuit 1110 may receive the reflected test signal TS as the reflection signal RS.

In operation S212, the storage controller 1100 may increase a delay time. For example, the storage controller 1100 may increase the delay time as much as one period or may increase the delay time as much as a time period smaller than one period.

In some embodiments, after the storage controller 1100 provides the test signal TS to the non-volatile memory device 1200, the storage controller 1100 may detect a sampling signal by sampling the reflection signal RS at a time point at which a second delay time whose length is longer than that of the first delay time elapses. As the delay time increases, the storage controller 1100 may detect a sampling signal corresponding to a more distant position from the storage controller 1100 in the channel or the second interface circuit 1210.

In operation S213, the storage controller 1100 may determine whether a voltage level of the sampling signal is greater than the first reference voltage level VREF1. For example, the storage controller 1100 may determine whether the first voltage level L1 at the first delay time (e.g., td1) is greater than the first reference voltage level VREF1. In some embodiments, the first interface circuit 1110 may perform the comparison operation on the first voltage level L1 and the first reference voltage level VREF1.

The first reference voltage level VREF1 may be greater than the voltage level of the first test signal and may be smaller than two times the voltage level of the first test signal. That is, the first reference voltage level VREF1 may be a voltage level corresponding to the case where the first test signal is reflected, with the termination of the second interface circuit 1210 opened.

In response to determining that the first voltage level L1 is not greater than the first reference voltage level VREF1, the storage controller 1100 may repeat operation S212 and operation S213.

In operation S214, in response to determining that the first voltage level L1 is greater than the first reference voltage level VREF1, the storage controller 1100 may determine a position of the ODT resistance 1212. For example, the storage controller 1100 may determine a position corresponding to the delay time of the first voltage level L1 as a position of the termination of the second interface circuit 1210 or the ODT resistance 1212.

FIG. 11 is a flowchart illustrating an operating method of a storage controller according to some embodiments of the present disclosure. Referring to FIGS. 2 and 11, the storage controller 1100 may determine the second reference voltage level VREF2. Operation S221 to operation S227 may constitute a portion of operation S220 of FIG. 9.

In operation S221, the storage controller 1100 may provide the test signal TS to the non-volatile memory device 1200.

In operation S222, the storage controller 1100 may decrease a delay time. For example, the storage controller 1100 may decrease the delay time as much as one period or may decrease the delay time as much as a time period smaller than one period.

In some embodiments, after the storage controller 1100 provides the test signal TS to the non-volatile memory device 1200, the storage controller 1100 may detect a sampling signal by sampling the reflection signal RS at a time point at which a second delay time whose length is shorter than that of the first delay time elapses. As the delay time decreases, the storage controller 1100 may detect a sampling signal corresponding to a closer position to the storage controller 1100 in the channel or the second interface circuit 1210.

In operation S223, the storage controller 1100 may determine whether a third voltage level (L3) of sampling data detected at a time point at which the second delay time elapses is higher than a test voltage level (VTEST). An initial value of the test voltage level may be the first reference voltage level VREF1 of FIGS. 4 and 10. For example, the storage controller 1100 may perform a comparison operation on the third voltage level and the test voltage level (e.g., a first test voltage level).

In operation S224, in response to determining that the third voltage level (L3) is not higher than (i.e., is lower than or equal to) the test voltage level, the storage controller 1100 may further decrease the test voltage level. For example, the storage controller 1100 may decrease the first test voltage level to a second test voltage level. In other words, the storage controller 1100 may decrease the test voltage level from a first test voltage level to a second test voltage level. For example, the test voltage level may initially be set to the first test voltage level, but the present disclosure is not limited thereto. When the first test voltage level is identical to the first reference voltage level VREF1, the second test voltage level may be lower than the first reference voltage level VREF1.

In operation S225, in response to determining that the third voltage level (L3) is higher than the test voltage level, the storage controller 1100 may decrease the delay time.

In some embodiments, after the storage controller 1100 provides the test signal TS to the non-volatile memory device 1200, the storage controller 1100 may detect a sampling signal by sampling the reflection signal RS at a time point at which a third delay time whose length is shorter than that of the second delay time elapses. As the delay time decreases, the storage controller 1100 may detect a sampling signal corresponding to a closer position to the storage controller 1100 in the channel or the second interface circuit 1210.

In operation S226, the storage controller 1100 may determine whether a fifth voltage level (L5) of a sampling signal detected at the third delay time is higher than the third voltage level (L3) of the sampling signal detected at the second delay time. That is, the storage controller 1100 may determine whether the third delay time corresponds to the inflection point at which the monotonous increase starts before the first reference voltage level VREF1.

In response to determining that the fifth voltage level (L5) of the sampling signal detected at the third delay time is not higher than the third voltage level (L3) of the sampling signal detected at the second delay time, the storage controller 1100 may repeat operation S223.

In operation S227, in response to determining that the fifth voltage level (L5) of the sampling signal detected at the third delay time is higher than the third voltage level (L3) of the sampling signal detected at the second delay time, the storage controller 1100 may determine the second reference voltage level VREF2. In some embodiments, the storage controller 1100 may determine the test voltage level VTEST (e.g., the first test voltage level) as the second reference voltage level VREF2. The second reference voltage level VREF2 may be a voltage level at a delay time corresponding to the position of the ODT resistance 1212 necessary for impedance matching.

FIG. 12 is a flowchart illustrating an operating method of a storage controller according to some embodiments of the present disclosure. Referring to FIGS. 2 and 12, the storage controller 1100 may determine a resistance value (e.g., a final resistance value) of the ODT resistance 1212. Operation S231 to operation S234 may constitute a portion of operation S230 of FIG. 9.

In operation S231, the storage controller 1100 may adjust the resistance value of the ODT resistance 1212. For example, the storage controller 1100 or the training module 1120 may adjust the resistance value of the ODT resistance 1212 to an arbitrary value.

In some embodiments, the storage controller 1100 or the training module 1120 may turn on the ODT resistance 1212 from a turn-off state and may adjust the resistance value of the ODT resistance 1212 to an arbitrary first value. The storage controller 1100 or the training module 1120 may provide the ODT control signal OCS to the ODT resistance 1212 to adjust the resistance value of the ODT resistance 1212.

In some embodiments, the storage controller 1100 or the training module 1120 may adjust resistance values of the plurality of ODT resistances 3212-1 to 3212-M of FIG. 7 to arbitrary values, respectively. Under control of the storage controller 1100, the plurality of ODT resistances 3212-1 to 3212-M may have different resistance values, and only some of the plurality of ODT resistances 3212-1 to 3212-M may be turned on.

In operation S232, the storage controller 1100 may provide the test signal TS to the non-volatile memory device 1200.

In operation S233, the storage controller 1100 may determine whether a voltage difference (D) between the fourth voltage level corresponding to the termination of the second interface circuit 1210 and the third voltage level corresponding to a point between the I/O pad 1211 and the termination is smaller than a threshold value (TH). That is, the storage controller 1100 may determine whether the impedance matching of the second interface circuit 1210 is completed as the resistance value of the ODT resistance 1212 is adjusted.

In response to determining that the voltage difference is not smaller than the threshold value, the storage controller 1100 may repeat operation S231.

In operation S234, in response to determining that the voltage difference is smaller than the threshold value, the storage controller 1100 may determine the final resistance value of the ODT resistance 1212. That is, in response to the voltage difference being smaller than the threshold value depending on the resistance value of the ODT resistance 1212 adjusted in operation S231, the storage controller 1100 may determine the resistance value adjusted in operation S231 as the final resistance value.

According to example embodiments of the present disclosure, a storage controller performing ODT training, an operating method of the storage controller, and an operating method of a storage system including the storage controller are provided.

Also, a storage controller which measures an impedance in an interface circuit based on a time domain reflectometry (TDR) of a reflection signal such that a position at which the impedance is discontinuous is quickly determined and ODT training is performed, an operating method of the storage controller, and an operating method of a storage system including the storage controller are provided.

As used herein, the terms “comprises”, “comprising”, “includes”, “including”, “has”, “having” and any other variations thereof specify the presence of the stated features, steps, operations, elements, components, and/or groups but do not preclude the presence or addition of one or more other features, steps, operations, elements, components, and/or groups thereof. In addition, it will be understood that, although the terms “first”, “second”, “third”, etc. may be used herein to describe various elements, these elements should not be limited by these terms. Rather, these terms are only used to distinguish one element from another. For example, a first element could be termed a second element, and, similarly, a second element could be termed a first element, without departing from the scope of the present disclosure. Further, as used herein, the term “and/or” includes any and all combinations of one or more of the associated listed items.

While the present disclosure has been described above with reference to example embodiments thereof, it will be apparent to those of ordinary skill in the art that various changes and modifications may be made thereto without departing from the scope of the present disclosure as set forth in the following claims.

What is claimed is:

1. An operating method of a storage controller which communicates with a non-volatile memory device, the method comprising:
after providing a first test signal to the non-volatile memory device, detecting first to N-th sampling signals at respective time points at which first to N-th delay times sequentially elapse;
determining the N-th sampling signal having a first voltage level higher than a first reference voltage level as a first target sampling signal, wherein the first reference voltage level is higher than a second voltage level of the first test signal and is lower than two times the second voltage level;
determining a K-th sampling signal, from among the first to N-th sampling signals, last having a third voltage level lower than a second reference voltage level as a second target sampling signal, wherein the second reference voltage level is lower than the first reference voltage level; and
after providing a second test signal to the non-volatile memory device, controlling an on-die termination (ODT) resistance of the non-volatile memory device such that a first difference between a fourth voltage level of a third target sampling signal detected at a time point at which the N-th delay time elapses and the third voltage level is smaller than a threshold value,
wherein “K” is an integer greater than 1, and “N” is an integer greater than “K”.

2. The method of claim 1, wherein the detecting of the first to N-th sampling signals comprises:
receiving a first reflection signal from the non-volatile memory device, wherein the first reflection signal is generated when the first test signal is reflected in the non-volatile memory device; and
detecting the first to N-th sampling signals by sampling the first reflection signal at the respective time points at which the first to N-th delay times sequentially elapse.

3. The method of claim 1, wherein the determining of the N-th sampling signal as the first target sampling signal comprises:
sequentially performing comparison operations on respective voltage levels of the first to N-th sampling signals and the first reference voltage level; and
determining that the first voltage level of the N-th sampling signal is higher than the first reference voltage level, in response to a result of the comparison operations.

4. The method of claim 1, wherein the determining of the K-th sampling signal as the second target sampling signal comprises:
performing a comparison operation on the third voltage level and a first test voltage level;
decreasing the first test voltage level to a second test voltage level in response to determining that the third voltage level is lower than or equal to the first test voltage level;
performing a comparison operation on the third voltage level and the second test voltage level;
performing a comparison operation on a fifth voltage level of a (K−1)-th sampling signal, from among the first to N-th sampling signals, and the third voltage level in response to determining that the third voltage level is higher than the second test voltage level; and
determining the K-th sampling signal as the second target sampling signal in response to determining that the fifth voltage level is higher than the third voltage level.

5. The method of claim 4, further comprising:
determining the first test voltage level as the second reference voltage level.

6. The method of claim 4, wherein the performing of the comparison operation on the third voltage level and the first test voltage level comprises:
performing a comparison operation on a sixth voltage level of a (K+1)-th sampling signal, from among the first to N-th sampling signals, and the first test voltage level;
performing a comparison operation on the third voltage level of the K-th sampling signal and the sixth voltage level in response to determining that the sixth voltage level is higher than the first test voltage level; and
performing the comparison operation on the third voltage level and the first test voltage level in response to determining that the sixth voltage level is lower than or equal to the third voltage level.

7. The method of claim 1, wherein the controlling of the ODT resistance of the non-volatile memory device such that the first difference is smaller than the threshold value comprises:
executing a training module for controlling the ODT resistance based on the second and third voltage levels;
determining a final value of the ODT resistance at which the first difference is smaller than the threshold value, based on the training module; and
controlling the ODT resistance based on the final value of the ODT resistance that was determined.

8. The method of claim 7, wherein the determining of the final value of the ODT resistance comprises:
controlling the ODT resistance such that the ODT resistance has a first value;
after providing the second test signal to the non-volatile memory device, detecting the third target sampling signal at a time point at which the N-th delay time elapses;
determining whether the first difference between the fourth voltage level of the third target sampling signal and the third voltage level is smaller than the threshold value; and
determining the first value as the final value of the ODT resistance in response to determining that the first difference is smaller than the threshold value.

9. The method of claim 8, wherein the controlling of the ODT resistance such that the ODT resistance has the first value comprises:
controlling the ODT resistance such that the ODT resistance has a second value;
after providing a third test signal to the non-volatile memory device, detecting a fourth target sampling signal at a time point at which the N-th delay time elapses;
determining whether a second difference between a fifth voltage level of the fourth target sampling signal and the third voltage level is smaller than the threshold value; and
in response to determining that the second difference is greater than or equal to the threshold value, controlling the ODT resistance such that the ODT resistance has the first value.

10. The method of claim 7, wherein the controlling of the ODT resistance based on the final value of the ODT resistance that was determined comprises:
generating an ODT control signal based on the final value of the ODT resistance; and
providing the ODT control signal to the non-volatile memory device.

11. The method of claim 7, wherein the ODT resistance includes first to M-th ODT resistances,
wherein the determining of the final value of the ODT resistance comprises:
controlling ones of ODT resistances among the first to M-th ODT resistances such that the ones of the ODT resistances have second to L-th values;
after providing the second test signal to the non-volatile memory device, detecting the third target sampling signal at a time point at which the N-th delay time elapses;
determining whether the first difference between the fourth voltage level of the third target sampling signal and the third voltage level is smaller than the threshold value; and
determining the second to L-th values as the final value of the ODT resistance in response to determining that the first difference is smaller than the threshold value, and
wherein “L” is an integer greater than 1, and “M” is an integer greater than “L”.

12. The method of claim 1, wherein the first to N-th delay times are sequentially delayed by one clock period or less.

13. A storage controller comprising:
an interface circuit configured to:
provide a first test signal and a second test signal to a non-volatile memory device; and
detect first to N-th sampling signals at respective time points at which first to N-th delay times sequentially elapse, after providing the first test signal to the non-volatile memory device;
a training module configured to generate an on-die termination (ODT) control signal for controlling an ODT resistance of the non-volatile memory device;
a voltage generator configured to generate a voltage having a first reference voltage level and a second reference voltage level; and
a timing circuit configured to provide a time signal indicating the first to N-th delay times to the interface circuit,
wherein the interface circuit is configured to determine the N-th sampling signal having a first voltage level higher than the first reference voltage level as a first target sampling signal, and to determine a K-th sampling signal, from among the first to N-th sampling signals, last having a third voltage level lower than the second reference voltage level as a second target sampling signal,
wherein, after the second test signal is provided to the non-volatile memory device, the training module is configured to determine a final resistance value of the ODT resistance such that a first difference between a fourth voltage level of a third target sampling signal detected at a time point at which the N-th delay time elapses and the third voltage level is smaller than a threshold value,
wherein the first reference voltage level is higher than a second voltage level of the first test signal and is lower than two times the second voltage level,
wherein the second reference voltage level is lower than the first reference voltage level, and
wherein “K” is an integer greater than 1, and “N” is an integer greater than “K”.

14. The storage controller of claim 13, wherein the interface circuit is configured to sequentially perform comparison operations on respective voltage levels of the first to N-th sampling signals and the first reference voltage level, and
wherein the training module is configured to determine that the first voltage level of the N-th sampling signal is higher than the first reference voltage level, in response to a result of the comparison operations.

15. The storage controller of claim 13, wherein the training module is configured to control the ODT resistance such that the ODT resistance has a first value, and
wherein the interface circuit is configured to determine the first value as the final resistance value of the ODT resistance in response to determining that the first difference is smaller than the threshold value.

16. An operating method of a storage system which includes a non-volatile memory device and a storage controller, the method comprising:
after providing a first test signal to the non-volatile memory device, detecting, by the storage controller, first to N-th sampling signals at respective time points at which first to N-th delay times sequentially elapse;
determining, by the storage controller, the N-th sampling signal having a first voltage level higher than a first reference voltage level as a first target sampling signal, wherein the first reference voltage level is higher than a second voltage level of the first test signal and is lower than two times the second voltage level;
determining, by the storage controller, a K-th sampling signal, from among the first to N-th sampling signals, last having a third voltage level lower than a second reference voltage level as a second target sampling signal, wherein the second reference voltage level is lower than the first reference voltage level; and
after providing a second test signal to the non-volatile memory device, controlling, by the storage controller, an on-die termination (ODT) resistance of the non-volatile memory device such that a first difference between a fourth voltage level of a third target sampling signal detected at a time point at which the N-th delay time elapses and the third voltage level is smaller than a threshold value,
wherein “K” is an integer greater than 1, and “N” is an integer greater than “K”.

17. The method of claim 16, wherein the detecting of the first to N-th sampling signals comprises:
receiving, by the storage controller, a first reflection signal from the non-volatile memory device, wherein the first reflection signal is generated when the first test signal is reflected in the non-volatile memory device; and
detecting, by the storage controller, the first to N-th sampling signals by sampling the first reflection signal at the respective time points at which the first to N-th delay times sequentially elapse.

18. The method of claim 16, wherein the determining of the N-th sampling signal as the first target sampling signal comprises:
sequentially performing, by the storage controller, comparison operations on respective voltage levels of the first to N-th sampling signals and the first reference voltage level; and
determining, by the storage controller, that the first voltage level of the N-th sampling signal is higher than the first reference voltage level, in response to a result of the comparison operations.

19. The method of claim 16, wherein the determining of the K-th sampling signal as the second target sampling signal comprises:
performing, by the storage controller, a comparison operation on the third voltage level and a first test voltage level;
decreasing, by the storage controller, the first test voltage level to a second test voltage level in response to determining that the third voltage level is lower than or equal to the first test voltage level;
performing, by the storage controller, a comparison operation on the third voltage level and the second test voltage level;
performing, by the storage controller, a comparison operation on a fifth voltage level of a (K−1)-th sampling signal, from among the first to N-th sampling signals, and the third voltage level in response to determining that the third voltage level is higher than the second test voltage level; and
determining, by the storage controller, the K-th sampling signal as the second target sampling signal in response to determining that the fifth voltage level is higher than the third voltage level.

20. The method of claim 19, wherein the performing of the comparison operation on the third voltage level and the first test voltage level comprises:
performing, by the storage controller, a comparison operation on a sixth voltage level of a (K+1)-th sampling signal, from among the first to N-th sampling signals, and the first test voltage level;
performing, by the storage controller, a comparison operation on the third voltage level of the K-th sampling signal and the sixth voltage level in response to determining that the sixth voltage level is higher than the first test voltage level; and
performing, by the storage controller, the comparison operation on the third voltage level and the first test voltage level in response to determining that the sixth voltage level is lower than or equal to the third voltage level.
